(19) United States
(12) Patent Application Publication
(10) Pub. No.: US 2026/0226612 A1
(43) Pub. Date: Aug. 6, 2026

(54) FILM-FORMING METHOD AND APPARATUS FOR TWO-DIMENSIONAL MATERIAL LAYER

(71) Applicant: Tokyo Electron Limited, Tokyo (JP)

(72) Inventors: Shinichi TANABE, Tokyo (JP); Atsuki FUKAZAWA, Tokyo (JP); Hiroki MAEHARA, Tokyo (JP)

(21) Appl. No.: 19/636,269

(22) Filed: Apr. 1, 2026

Related U.S. Application Data
(63) Continuation of application No. PCT/JP2024/035657, filed on Oct. 4, 2024.

(30) Foreign Application Priority Data
Oct. 11, 2023 (JP) 2023-176113

(51) Int. Cl. C23C 16/30; C23C 16/455; C23C 16/458; C23C 16/52

(52) U.S. Cl. CPC C23C 16/305; C23C 16/45563; C23C 16/4584; C23C 16/52

(57) ABSTRACT

A film-forming method for a two-dimensional material layer is provided and includes providing a substrate in which a portion of an underlayer is exposed from a two-dimensional material layer formed over the underlayer; supplying a liquid precursor raw material including a transition metal to the substrate; and supplying a gas including a chalcogen element, thereby forming the two-dimensional material layer over the exposed underlayer.

### CROSS-REFERENCE TO RELATED APPLICATIONS

This application is a continuation application of International Application No. PCT/JP2024/035657, filed on October 4, 2024, and designated the U.S., which is based upon and claims priority to Japanese Patent Application No. 2023-176113, filed on October 11, 2023, the entire contents of which are incorporated herein by reference.

### BACKGROUND

### 1. Field of the Invention

The present disclosure relates to a film-forming method and apparatus for a two-dimensional material layer.

### 2. Description of the Related Art

For example, Japanese Laid-Open Patent Application Publication No. 2022-37889 proposes a method of forming a two-dimensional film of a transition metal chalcogenide by using an apparatus configured to perform: oxidizing a transition metal block to form an oxide layer of a transition metal on a surface of the transition metal block; sublimating an oxide from the oxide layer to supply a gas of the oxide to a substrate along with a first inert carrier gas through a dedicated tube; supplying a reactive gas including chalcogen atoms to the substrate along with a second inert carrier gas; heating the substrate at the time of supplying the gas of the oxide and the reactive gas to the substrate; and exhausting the gas of the oxide, the reactive gas, the first inert carrier gas, and the second inert carrier gas.

### SUMMARY

According to one aspect of the present disclosure, a film-forming method for a two-dimensional material layer includes: (A) providing a substrate in which a portion of an underlayer is exposed from a two-dimensional material layer formed over the underlayer; (B) supplying a liquid precursor raw material including a transition metal onto the substrate; and (C) supplying a gas including a chalcogen element, thereby forming the two-dimensional material layer over the exposed underlayer.

### BRIEF DESCRIPTION OF THE DRAWINGS

FIG. 1 is a diagram illustrating an example of a film structure formed by a conventional film-forming method for a two-dimensional material layer.

FIG. 2 is a diagram illustrating another example of the film structure formed by the conventional film-forming method for the two-dimensional material layer.

FIG. 3 is a flowchart illustrating an example of a film-forming method for a two-dimensional material layer according to an embodiment of the present disclosure.

FIG. 4 is a diagram illustrating an example of a film structure formed by the film-forming method illustrated in FIG. 3.

FIG. 5 is a longitudinal cross-sectional diagram illustrating an example of a film-forming apparatus according to an embodiment of the present disclosure.

FIG. 6 is a diagram illustrating an example of a film structure formed by another example of the film-forming method for the two-dimensional material layer according to the embodiment.

### DETAILED DESCRIPTION OF THE DISCLOSURE

The present disclosure provides a technique of selectively supplying a precursor raw material to a surface of an underlayer not covered by a two-dimensional material layer, thereby forming a continuous two-dimensional material layer.

Hereinafter, embodiments of the present disclosure will be described with reference to the drawings. In the drawings, the same components are denoted by the same reference signs, and thus duplicate descriptions may be omitted.

### Formation of Conventional Metal Chalcogen-Including Film

A transition metal chalcogenide layer is expected as a next-generation transistor channel material. The transition metal chalcogenide layer (TMDC: transition metal dichalcogenides) is a two-dimensional material layer in which a transition metal, such as molybdenum (Mo), tungsten (W), or the like, and a chalcogen element, such as sulfur (S), selenium (Se), tellurium (Te), or the like, are bonded in the form of a planar sheet and are laminated. Examples of the transition metal chalcogenide layers include WSe₂, WS₂, MoSe₂, MoS₂, and the like.

A conventional MoS₂ film-forming method is, for example, forming an MoS₂ film through chalcogenization of an Mo or MoOₓ film with sulfur, hydrogen sulfide, or organic sulfur. The Mo or MoOₓ film can be formed through PVD (Physical Vapor Deposition), CVD (Chemical Vapor Deposition), ALD (Atomic Layer Deposition), or vacuum vapor deposition. Another MoS₂ film-forming method is forming an MoS₂ film through a reaction between a molybdenum-including raw material gas and a gas of sulfur, hydrogen sulfide, or organic sulfur through CVD, ALD, or the like.

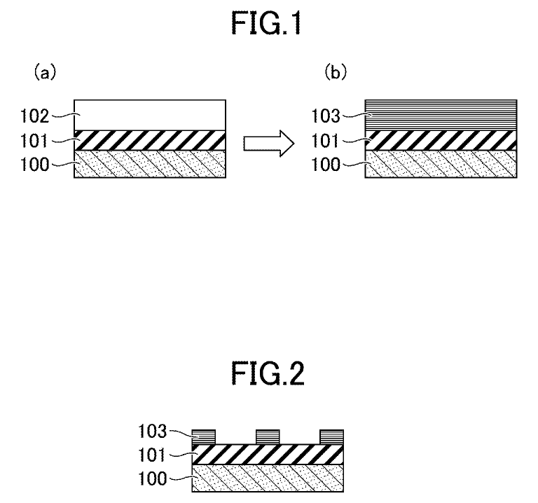

FIG. 1 is a diagram illustrating an example of a film structure formed by a conventional film-forming method for a two-dimensional material layer. Specifically, (a) and (b) of FIG. 1 illustrate an example of forming an MoS₂ film through chalcogenization of an MoOₓ film with sulfur. As illustrated in (a) of FIG. 1, an MoOₓ film 102 is formed over an SiO₂ (silicon oxide) film 101 of a silicon substrate 100.

For obtaining the MoS₂ film, the MoOₓ film 102 is chalcogenized. When the MoOₓ film 102 is heated in an atmosphere of a gas including sulfur (S), Mo and S react with each other to form an MoS₂ film 103 from the MoOₓ film 102. However, it is challenging to obtain the MoOₓ film 102 as a layer of one to several atoms, and a typical film thickness of the obtained MoOₓ film is several nanometers.

Suflurization of the MoOₓ film 102 having a film thickness of several nanometers, as illustrated in (b) of FIG. 1, results in the multilayered MoS₂ film 103. This precludes formation of a thin MoS₂ film, i.e., a layer of one to several atoms. Since mobility increases the thinner the MoS₂ film 103 is, such multilayering of the MoS₂ film 103 leads to the problem of degraded mobility.

When the thin MoS₂ film, i.e., the layer of one to several atoms, is to be formed through CVD, ALD, PVD, vacuum vapor deposition, or the like, a discontinuous MoS₂ film, in which an SiO₂ film, i.e., an underlayer, is exposed, tends to be formed. That is, as illustrated in FIG. 2, the MoS₂ film 103 does not form a film in the form of a sheet. Even if the film formation is to be additionally performed through CVD, ALD, PVD, vacuum vapor deposition, or the like, it is challenging to selectively supply a raw material to the surface of the SiO₂ film 101 because the raw material is supplied to the entire surface of the MoS₂ film 103 and the SiO₂ film 101. As a result, MoS₂ grows on the MoS₂ film 103, and thus the discontinuous film is multilayered.

In view of this, as a technique of the additional film formation, the film-forming method according to the present embodiment employs a liquid precursor raw material including molybdenum (hereinafter also referred to as an Mo-including liquid) and selectively supplies the Mo-including liquid onto the SiO₂ film 101.

When the Mo-including liquid is supplied to the exposed portions of the discontinuous film of the hydrophobic MoS₂ film 103 and the hydrophilic underlayer surface (the SiO₂ film 101 in the example of FIG. 1), the surface of the hydrophobic MoS₂ film 103 repels the Mo-including liquid. Then, the SiO₂ film 101 having excellent liquid wettability is selectively covered by the Mo-including liquid. Therefore, it is possible to supply the Mo-including liquid to the surfaces other than the MoS₂ film 103.

Thus, the Mo-including liquid can be selectively supplied onto the SiO₂ film 101 in which the MoS₂ film 103 is absent. As a result, the MoS₂ film 103 is additionally formed in a lateral direction to fill the exposed portions of the SiO₂ film 101, thereby making the discontinuous film of the MoS₂ film 103 continuous. Further, the thin MoS₂ film 103 can be formed. Thus, it is possible to form the MoS₂ film 103 having high mobility.

### Film-Forming Method

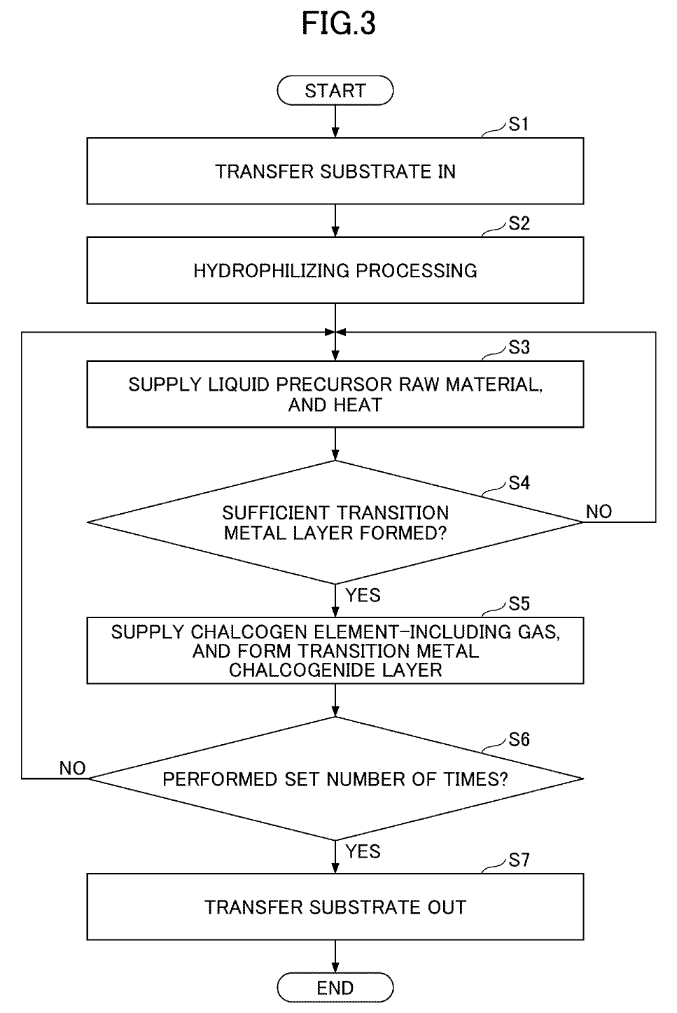

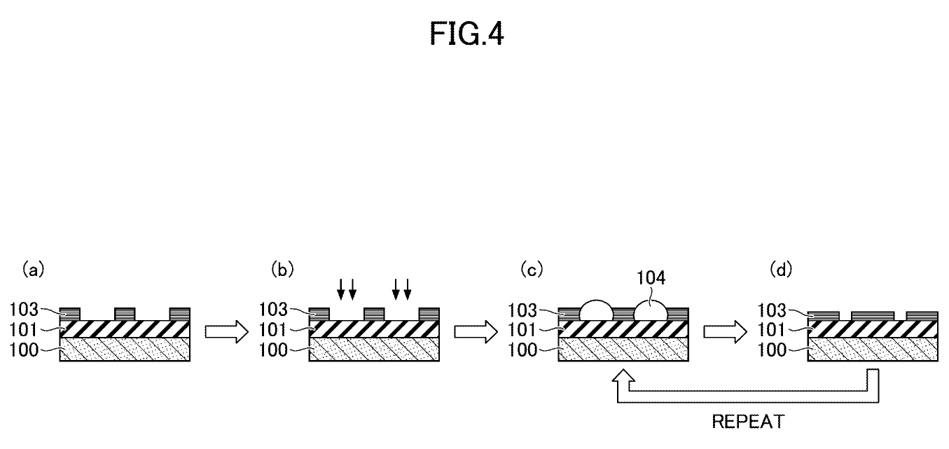

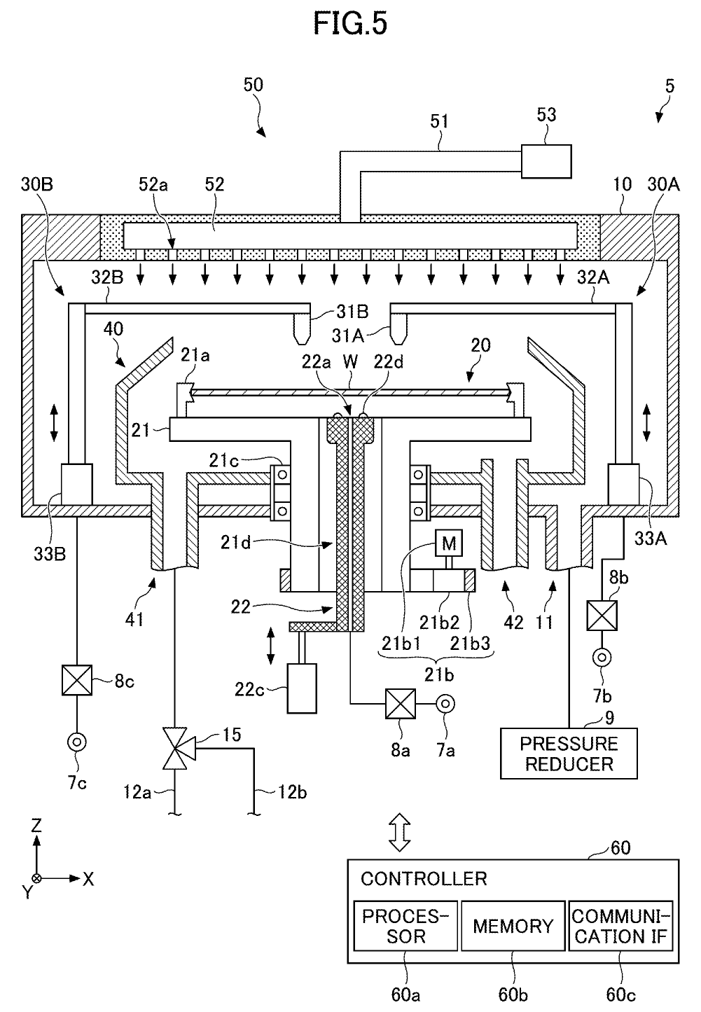

The film-forming method for the two-dimensional material layer according to the embodiment will be described with reference to FIGS. 3 and 4. FIG. 3 is a flowchart illustrating an example of the film-forming method for the two-dimensional material layer according to the embodiment. FIG. 4 is a diagram illustrating an example of a film structure formed by the film-forming method illustrated in FIG. 3.

The present process is performed on a substrate in which a discontinuous film of a transition metal layer, an oxide film layer of a transition metal, or a transition metal chalcogenide layer is previously formed over an underlayer. These layers are formed over the underlayer through CVD, ALD, PVD, vacuum vapor deposition, or the like. However, when forming the film to be a thin film of a layer of one to several atoms as described above, a discontinuous film is formed in which the underlayer is partially exposed. The following description will be made taking, as an example, a case in which a discontinuous MoS₂ film including Mo as a transition metal is formed.

For example, when the film thickness of the MoS₂ film is 2.2 nanometers (nm) or less, it is considered that a discontinuous film of MoS₂ is formed over the underlayer. In this case, the underlayer is partially exposed from the MoS₂ film. The substrate in this state is transferred into a film-forming apparatus configured to perform the film-forming method for the two-dimensional material layer according to the embodiment.

In step S1, the substrate in which the MoS₂ film 103 is discontinuously formed over the SiO₂ film 101 is transferred into the film-forming apparatus, i.e., the substrate is provided. Specifically, as illustrated in (a) of FIG. 4, the substrate in which portions of the SiO₂ film 101 are exposed from the MoS₂ film 103 formed over the SiO₂ film 101 is provided.

In step S2, the surface of the substrate is subjected to hydrophilizing processing. As illustrated in (b) of FIG. 4, the hydrophilizing processing is supplying a hydrophilizing processing liquid for hydrophilizing the surface of the SiO₂ film 101. The hydrophilizing processing liquid for use can be, for example, a chemical liquid including ozone water, a chemical liquid including SPM (sulfuric acid-hydrogen peroxide mixture), or the like. However, the hydrophilizing processing liquid is not limited to these. As another method, the surface of the substrate is washed with hydrogen peroxide and sulfuric acid, and then washed off with water. As yet another method, the surface of the substrate may be irradiated with UV light.

When the surface of the underlayer is hydrophilic, step S2 may be omitted. The recitation that the surface of the underlayer is hydrophilic means that the surface of the underlayer has sufficient wettability to the supplied liquid precursor raw material in the processing of step S3 described below. When the hydrophilicity of the surface of the underlayer is lost, it is better to perform the hydrophilizing processing of step S2, but the hydrophilizing processing of step S2 may be omitted.

In step S3, the Mo-including liquid, i.e., an example of a liquid precursor raw material, is supplied to the substrate. As illustrated in (c) of FIG. 4, when an Mo-including liquid 104 is supplied, the surface of the hydrophobic MoS₂ film 103 repels the Mo-including liquid 104, and thus the SiO₂ film 101 having excellent liquid wettability is selectively covered by the Mo-including liquid 104. Therefore, the Mo-including liquid can be supplied to the surfaces other than the MoS₂ film 103. That is, the Mo-including liquid 104 can be supplied to the surface of the SiO₂ film 101, i.e., the underlayer, rather than the surface of the MoS₂ film 103. As a result, the Mo-including liquid 104 is also supplied to the edges (side surfaces) of the surface of the MoS₂ film 103. Subsequently, the Mo-including liquid 104 is heated to evaporate the solvent included in the Mo-including liquid 104, thereby forming an Mo layer over the substrate surface. The Mo layer is an example of a transition metal layer. In accordance with the type of a liquid precursor to be used, the transition metal layer (Mo layer) formed by evaporating the solvent can be an oxygen-including transition metal oxide layer (MoOx layer) or can be a nitrogen-including transition metal nitride layer (MoNx layer). In the present specification, for the sake of convenience, the MoOx layer and the MoNx layer are collectively referred to as the transition metal layer (Mo layer). As in the case of chalcogenization of the MoOx film described above, a transition metal layer including impurities can be chalcogenized. The transition metal layer, the transition metal oxide layer, and the transition metal nitride layer are examples of a transition metal-including layer.

In step S4, it is determined whether or not a sufficient transition metal layer (Mo layer) has been formed. In step S4, steps S3 and S4 are repeatedly performed until it is determined that a sufficient transition metal layer (Mo layer) has been formed. When it is determined that a sufficient transition metal layer (Mo layer) has been formed, the process proceeds to step S5. In this manner, after forming a sufficient transition metal layer (Mo layer) covering the exposed portions of the SiO₂ film 101 by repeatedly performing step S3 a plurality of times, the transition metal layer (Mo layer) may be chalcogenized in step S5. The recitation of forming a sufficient transition metal layer (Mo layer) means, for example, forming a transition metal layer (Mo layer) having a predetermined thickness or larger.

In step S5, in a state in which the substrate is heated, the Mo layer is chalcogenized by supply of a chalcogen element-including gas (a gas including a chalcogen element), thereby forming a two-dimensional material layer (transition metal chalcogenide layer). For example, a sulfur-including gas (a gas including sulfur) is supplied as an example of the chalcogen element-including gas. The Mo layer formed over the surface of the substrate (underlayer) reacts with sulfur in the gas to be chalcogenized (chalcogenided), thereby forming an MoS₂ film, i.e., an example of the transition metal chalcogenide layer.

As illustrated in (d) of FIG. 4, the edges (side surfaces) of the MoS₂ film 103 serve as the origin of growth, and the MoS₂ film 103 grows in a lateral direction (horizontal direction) of the silicon substrate 100. Thus, the MoS₂ film is formed in the direction in which the exposed portions of the SiO₂ film 101 are filled.

In step S6, it is determined whether or not the process has been performed a previously set number of times. If it is determined in step S6 that the process has not been the set number of times, the process returns to step S3 to repeatedly perform steps S3 to S6. However, if it is determined in step S6 that the process has not been performed the set number of times, the process may return to step S2 to repeatedly perform steps S2 to S6.

If it is determined in step S6 that the process has been performed the set number of times, the exposed portions of the SiO₂ film 101 are filled, thereby forming the continuous MoS₂ film 103. In step S7, the substrate is transferred out.

According to the film-forming method for the two-dimensional material layer according to the present embodiment, by use of the difference in liquid wettability, the Mo-including liquid is selectively supplied to the surface of the underlayer subjected to the hydrophilizing processing. That is, the Mo-including liquid is selectively supplied to the underlayer in which the MoS₂ film is absent. The Mo-including liquid is used to promote the formation of the MoS₂ film 103 starting from the edges of the segments of the discontinuous MoS₂ films 103, and the discontinuous MoS₂ films 103 can be bonded to each other to form the continuous MoS₂ film 103.

Although the present embodiment takes SiO₂ as an example of the underlayer, the underlayer is not limited to this. A high-k material, such as HfiO₂, ZrO₂, or the like, can be the underlayer. The liquid precursor raw material includes, for example, a transition metal, and is supplied as a liquid in which a raw material of molybdenum (Mo) or tungsten (W) is dissolved in a solvent. For example, the liquid precursor raw material may be MoO₃, (NH₄)₂MoS₄, or WoO₃. For example, the solvent may be (NH₄)OH, H₂O, N, or N-dimethylformamide.

An additive may be added to the liquid precursor raw material before supply. The additive is used to increase the film-forming rate. The additive may include an alkali metal, such as K, Na, or the like, or a halide of F, Cl, Br, I, or the like.

The chalcogenization of the liquid precursor raw material includes sulfurization due to sulfur (S), H₂S, or organic sulfur, selenization due to selenium (Se), H₂Se, or organic selenium, tellurization due to tellurium (Te), H₂Te, or organic tellurium.

The two-dimensional material layer formed over the substrate is the transition metal chalcogenide layer, and the material of the two-dimensional material layer may include a transition metal element and a chalcogen element. The chalcogen element includes sulfur (S), selenium (Se), or tellurium (Te). The two-dimensional material layer includes MoS₂, MoSe₂, MoTe₂, WS₂, WSe₂, or WTe₂.

### Configuration of Film-Forming Apparatus

Next, the configuration and operation of a film-forming apparatus 5 configured to perform the film-forming process according to the present embodiment will be specifically described. FIG. 5 is a longitudinal cross-sectional diagram illustrating an example of the film-forming apparatus according to the embodiment of the present disclosure.

The film-forming apparatus 5 includes a substrate holder 20, liquid supplies 30A and 30B, a recovery cup 40, and a gas supply 50, in a chamber 10 defining a processing chamber configured to be reduced in pressure.

The substrate holder 20 is provided in the chamber 10 (processing chamber) and is configured to hold a substrate W. The substrate holder 20 includes: a rotation holder 21 configured to rotatably hold the substrate W; and a gas supply 22 inserted into a hollow portion 21d of the rotation holder 21 and configured to supply a gas to the bottom surface of the substrate W.

The rotation holder 21 is provided substantially at the center of the chamber 10. A holder 21a configured to hold the substrate W from the side surface is provided at the top surface of the rotation holder 21. The substrate W is horizontally held by the holder 21a in a state of being slightly separated from the top surface of the rotation holder 21.

The rotation holder 21 includes a driver 21b, and is configured to rotate about a vertical axis using the driver 21b. Specifically, the driver 21b includes: a motor 21b1; a pulley 21b2 attached to the output shaft of the motor 21b1; and a belt 21b3 wound around the outer circumference of the pulley 21b2 and the rotation holder 21.

The driver 21b is configured to rotate the pulley 21b2 by the rotation of the motor 21b1, and transmit the rotation of the pulley 21b2 to the rotation holder 21 using the belt 21b3, thereby rotating the rotation holder 21 about the vertical axis. In accordance with the rotation of the rotation holder 21, the substrate W held by the rotation holder 21 rotates integrally with the rotation holder 21. The rotation holder 21 is rotatably supported via a bearing 21c by the chamber 10 and the recovery cup 40.

The gas supply 22 is an elongated member inserted into the hollow portion 21d formed at the center of the rotation holder 21. A flow path 22a is formed in the gas supply 22. An N₂ supply source 7a is connected to the flow path 22a via a valve 8a. The gas supply 22 is configured to supply the N₂ gas, supplied from the N₂ supply source 7a, to the bottom surface of the substrate W via the valve 8a and the flow path 22a.

The N₂ gas supplied via the valve 8a is a high-temperature (e.g., about 100°C) N₂ gas, and is used for heating the liquid precursor raw material described below. The gas supply 22 is an example of a heater configured to heat the substrate W.

The gas supply 22 is also used for delivery of the substrate W. Specifically, a raising/lowering mechanism 22c configured to vertically move the gas supply 22 is provided at the base end of the gas supply 22. Further, supporting pins 22d configured to support the substrate W are provided at the top surface of the gas supply 22.

When the substrate holder 20 receives the substrate W from a substrate transfer apparatus (not shown), the substrate holder 20 raises the gas supply 22 using the raising/lowering mechanism 22c, and places the substrate W on the tops of the supporting pins 22d. Subsequently, the substrate holder 20 lowers the gas supply 22 to a predetermined position, and then delivers the substrate W to the holder 21a of the rotation holder 21. When the substrate holder 20 delivers the already processed substrate W to the substrate transfer apparatus, the substrate holder 20 raises the gas supply 22 using the raising/lowering mechanism 22c, and places the substrate W, held by the holder 21a, onto the supporting pins 22d. Then, the substrate holder 20 delivers the substrate W, placed on the supporting pins 22d, to the substrate transfer apparatus.

Each of the liquid supplies 30A and 30B is configured to move from the outside of the substrate W to a position above the substrate W, and supply the processing liquid toward the top surface of the substrate W held by the substrate holder 20. The liquid supply 30A includes: a nozzle 31A; an arm 32A configured to horizontally support the nozzle 31A; and a turning and raising/lowering mechanism 33A configured to turn and raise/lower the arm 32A. Also, the liquid supply 30B includes: a nozzle 31B; an arm 32B configured to horizontally support the nozzle 31B; and a turning and raising/lowering mechanism 33B configured to turn and raise/lower the arm 32B.

The liquid supply 30A supplies the liquid precursor raw material to the substrate W from the nozzle 31A. Specifically, a raw material supply source 7b is connected to the nozzle 31A via a valve 8b, and the liquid precursor raw material supplied from the raw material supply source 7b is supplied from the nozzle 31A onto the substrate W. The nozzle 31A is an example of a first nozzle configured to supply a transition metal-including liquid precursor raw material to the surface of the substrate W.

The liquid supply 30B supplies the hydrophilizing processing liquid from the nozzle 31B to the substrate W. Specifically, a removing liquid supply source 7c is connected to the nozzle 31B via a valve 8c, and the hydrophilizing processing liquid supplied from the removing liquid supply source 7c is supplied from the nozzle 31B onto the substrate W. The nozzle 31B is an example of a second nozzle configured to supply the hydrophilizing processing liquid used for performing the hydrophilizing processing on the surface of the substrate W.

Although the nozzles 31A and 31B dedicated to the respective processing liquids are provided here, the nozzles may be shared by a plurality of processing liquids. For example, the liquid precursor raw material and the hydrophilizing processing liquid may be selectively supplied from the nozzle 31A and the nozzle 31B. However, for example, when it is undesired to mix the processing liquids, the shared nozzle requires a step of discharging the processing liquid remaining in the nozzle and the tube, resulting in wasteful consumption of the processing liquid. Whereas, when the nozzles 31A and 31B are dedicated to the respective processing liquids, the step of discharging the processing liquid is not required, and thus the processing liquid is not wastefully consumed.

The recovery cup 40 is disposed to enclose the rotation holder 21 for preventing scattering of the processing liquid to the surroundings. A liquid discharge port 41 is formed at the bottom of the recovery cup 40, and the processing liquid recovered in the recovery cup 40 is discharged from the liquid discharge port 41 to the outside of the film-forming apparatus 5. Also, a gas discharge port 42 is formed at the bottom of the recovery cup 40, and the N₂ gas supplied by the gas supply 22 or the gas supplied into the film-forming apparatus 5 from the gas supply 50 described below is discharged from the gas discharge port 42 to the outside of the film-forming apparatus 5.

The liquid discharge port 41 is provided with a waste liquid line 12a and a recovery line 12b, and the waste liquid line 12a and the recovery line 12b are switchable by a switching valve 15. The film-forming apparatus 5 switches between the waste liquid line 12a and the recovery line 12b using the switching valve 15, thereby discharging a reusable liquid to the recovery line 12b and discharging the other liquids to the waste liquid line 12a.

A gas discharge port 11 is formed at the bottom of the chamber 10, and a pressure reducer 9 is connected to the gas discharge port 11. The pressure reducer 9 is, for example, a vacuum pump, and is configured to reduce the interior of the chamber 10 in pressure through suction.

The gas supply 50 is attached to the ceiling of the chamber 10, and is configured to supply the chalcogen element-including gas into the chamber 10. Specifically, the gas supply 50 includes a gas supply 53, a gas supply tube 51, and a buffer chamber 52 communicating with the gas supply tube 51. The gas supply tube 51 is connected to the gas supply 53. A plurality of communication holes 52a, communicating the buffer chamber 52 with the interior of the chamber 10, are formed at the bottom of the buffer chamber 52.

The gas supply 50 is configured to supply the chalcogen element-including gas to the buffer chamber 52 through the gas supply tube 51. Then, the gas supply 50 is configured to supply the chalcogen element-including gas, supplied to the buffer chamber 52, into the chamber 10 through the plurality of communication holes 52a. Thus, the chalcogen element-including gas is supplied into the chamber 10.

A controller 60 is configured to process computer-executable instructions causing the film-forming apparatus 5 to perform the steps described in the present disclosure. The controller 60 may be configured to control the components of the film-forming apparatus 5 to perform the steps described in the present disclosure. In the embodiment, a part or all of the controller 60 may be included in the film-forming apparatus 5. The controller 60 may include a processor 60a, a memory 60b, and a communication interface 60c. The controller 60 is, for example, implemented by a computer. The processor 60a can be configured to perform various control operations by reading out a program from the memory 60b and executing the read-out program. This program may be previously stored in the memory 60b, or may be obtained from a medium when necessary. The obtained program is stored in the memory 60b, and read by the processor 60a from the memory 60b to be executed. The medium may be any storage medium that is readable by a computer 2a, or may be a communication line connected to the communication interface 60c. The processor 60a may be a CPU (Central Processing Unit). The memory 60b may include a RAM (Random Access Memory), a ROM (Read Only Memory), an HDD (Hard Disk Drive), an SSD (Solid State Drive), or a combination of these. The communication interface 60c may communicate with the film-forming apparatus 5 via a communication line, such as a LAN (Local Area Network) or the like.

### Operation of Film-Forming Apparatus

### Substrate-Providing Processing

In the film-forming apparatus 5, first, a substrate is transferred into the chamber 10, and held by the substrate holder 20. Over the underlayer of the substrate transferred into the film-forming apparatus 5, a discontinuous film of a transition metal layer, an oxide film layer of a transition metal, or a transition metal chalcogenide layer is formed. In this substrate-providing processing, after the substrate transfer apparatus places the substrate W on the supporting pins 22d, the substrate W is held by the holder 21a of the rotation holder 21. At this time, the substrate W is held by the holder 21a in a state in which the circuit-formed surface faces upward. Subsequently, the rotation holder 21 is rotated by the driver 21b. Thus, the substrate W is horizontally held by the rotation holder 21, and rotates along with the rotation holder 21.

### Hydrophilizing Processing

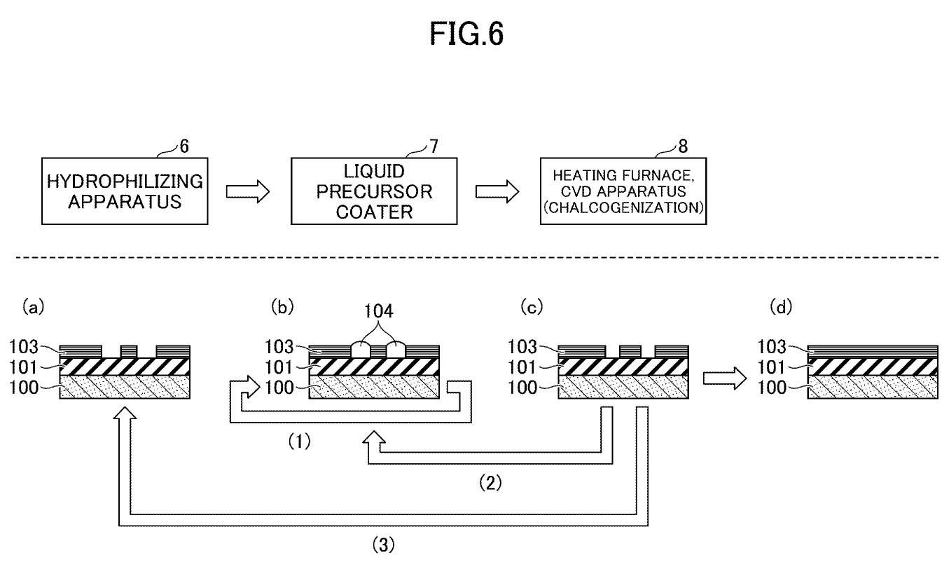

Subsequently, hydrophilizing processing is performed in the film-forming apparatus 5. The hydrophilizing processing is processing of supplying, to the substrate W, a hydrophilizing processing liquid, e.g., a chemical liquid including ozone water or a chemical liquid including SPM. Specifically, the nozzle 31B of the liquid supply 30B is positioned above the center of the substrate W, and then the hydrophilizing processing liquid is supplied from the nozzle 31B to the top surface of the substrate W. The hydrophilizing processing liquid supplied to the top surface of the substrate W hydrophilizes the surface of the SiO₂ film 101, exposed on the top surface of the substrate W, due to a centrifugal force caused by the rotation of the substrate W. When the substrate W illustrated in (a) of FIG. 6 is transferred into the chamber 10, followed by the hydrophilizing processing performed on the substrate W, the MoS₂ film 103 remains hydrophobic, and the surface of the SiO₂ film 101 becomes hydrophilic.

### Liquid Precursor Raw Material Supply Processing

Subsequently, liquid precursor raw material supply processing is performed in the film-forming apparatus 5. In this liquid precursor raw material supply processing, the nozzle 31A of the liquid supply 30A is positioned above the center of the substrate W, and then the Mo-including liquid, i.e., an example of an Mo-including liquid precursor raw material, is supplied from the nozzle 31A to the top surface of the substrate W. The Mo-including liquid supplied to the top surface of the substrate W is supplied to the SiO₂ film 101, exposed on the top surface of the substrate W, due to a centrifugal force caused by the rotation of the substrate W. In other words, the MoS₂ film 103 repels the Mo-including liquid due to its hydrophobicity, but the hydrophilic surface of the SiO₂ film 101 causes the Mo-including liquid 104 to gather on the SiO₂ film 101 exposed between the segments of the MoS₂ films 103, as illustrated in (b) of FIG. 6. Subsequently, the Mo-including liquid 104 is heated to evaporate the solvent included in the Mo-including liquid 104, thereby forming an Mo layer over the substrate surface. The supply and heating of the Mo-including liquid 104 are repeatedly performed until a sufficient Mo layer is formed (see (1) of FIG. 6).

When the valve 8a is opened for a predetermined period, a high-temperature N₂ gas is supplied from the gas supply 22 to the bottom surface of the rotating substrate W. Thus, the liquid precursor raw material is heated along with the substrate W, thereby accelerating volatilization of the solvent included in the liquid precursor raw material.

Also, the interior of the chamber 10 is reduced in pressure by the pressure reducer 9. This also accelerates the volatilization of the solvent of the liquid precursor raw material. When the solvent volatilizes, Mo, i.e., the precursor raw material, remains to form an Mo layer. The supply of the liquid precursor raw material and the volatilization of the solvent may be performed as one set a plurality of times. This can form the Mo layer sufficient to fill the exposed portions of the SiO₂ film 101.

### Chalcogenization Processing

Subsequently, chalcogenization processing is performed in the film-forming apparatus 5 in a state in which the substrate is heated. Specifically, the gas supply 50 supplies a sulfur-including gas, i.e., the chalcogen element-including gas, from the gas supply 53 to the buffer chamber 52. The gas supply 50 supplies the sulfur-including gas, supplied to the buffer chamber 52, into the chamber 10 through the plurality of communication holes 52a. Thus, the sulfur-including gas is supplied into the chamber 10.

Mo reacts with sulfur included in the gas, and the precursor raw material is chalcogenized by sulfur, thereby forming the MoS₂ film 103. Thus, additional film formation of the MoS₂ film 103 can be performed.

In this additional film formation, the discontinuous MoS₂ film 103 is grown in the lateral direction of the substrate. Therefore, as illustrated in (c) of FIG. 6, the discontinuous portions of the MoS₂ film 103, i.e., the exposed portions of the SiO₂ film 101, are gradually narrowed by this additional film formation, and the MoS₂ film 103 is formed in the lateral direction to fill the exposed portions of the SiO₂ film 101.

The set number of times until filling of the exposed portions of the SiO₂ film 101 is previously obtained through simulations or experiments. Therefore, as illustrated in (2) of FIG. 6, the supply of the liquid precursor raw material and the volatilization of the solvent in (b) of FIG. 6, and the chalcogenization in (c) of FIG. 6 are repeatedly performed the previously set number of times. Alternatively, after forming the Mo layer sufficient to fill the exposed portions of the SiO₂ film 101 by repeatedly performing the supply of the liquid precursor raw material and the volatilization of the solvent the previously set number of times, the chalcogenization in (c) of FIG. 6 is performed.

Thus, as illustrated in (d) of FIG. 6, the MoS₂ film 103 can be grown in the lateral direction to fill the exposed portions of the SiO₂ film 101. Thus, by using the discontinuous MoS₂ film 103, it is possible to form a continuous film of the thin MoS₂ film 103 of one to several atoms. Thus, the MoS₂ film 103 having high mobility can be formed.

When the hydrophilicity of the surface of the SiO₂ film 101 is lost by the application of the Mo-including liquid 104, as illustrated in (3) of FIG. 6, it is preferable to repeat the process including the hydrophilizing processing in (a) of FIG. 6. Thus, after the surface of the SiO₂ film 101 is caused to be hydrophilic, the liquid precursor raw material (Mo-including liquid) can be supplied as illustrated in (b) of FIG. 6. This can more selectively supply the liquid precursor raw material to the surface of the SiO₂ film 101. In this case, the hydrophilizing processing, the supply of the liquid precursor raw material, and the chalcogenization processing of the precursor raw material are repeatedly performed the previously set number of times.

During the repeated processing illustrated in (2) of FIG. 6, the repeated processing illustrated in (3) of FIG. 6 may be performed at a desired frequency. When the hydrophilicity of the surface of the SiO₂ film 101 is lost during the repeated processing illustrated in (2) of FIG. 6, the repeated process illustrated in (3) of FIG. 6 may be performed. Whether or not the hydrophilicity of the surface of the SiO₂ film 101 is lost can be determined in accordance with the contact angle of the Mo-including liquid 104.

### Substrate Transfer-Out Processing

After completion of the formation of the continuous MoS₂ film 103 as illustrated in (d) of FIG. 6, substrate transfer-out processing is performed in the film-forming apparatus 5. In this substrate transfer-out processing, the gas supply 22 is raised by the raising/lowering mechanism 22c, and the substrate W held by the holder 21a is placed on the supporting pins 22d. Then, the substrate W placed on the supporting pins 22d is delivered to the substrate transfer apparatus. When the substrate transfer-out processing is completed, the MoS₂ film-forming processing for one substrate W is completed.

The controller 60 is configured to control:
(A) holding the substrate at the substrate holder 20;
(B) supplying the transition metal-including liquid precursor raw material onto the substrate; and
(C) supplying the chalcogen element-including gas, thereby forming the two-dimensional material layer over the exposed underlayer. The controller 60 is configured to repeatedly perform (B) and (C) in order the previously set number of times. The hydrophilizing processing may be performed before (B). In this case, the controller 60 may repeatedly perform the hydrophilizing processing, (B), and (C) in order the previously set number of times.

The controller 60 controls the heater to heat the substrate W and volatilize the solvent included in the liquid precursor raw material. In (C), the controller 60 forms the two-dimensional material layer (transition metal chalcogenide layer) by supplying the chalcogen element-including gas into the chamber 10 in a state in which the substrate W is heated after volatilizing the solvent included in the liquid precursor raw material. In (A), the substrate W held by the substrate holder 20 is provided with the two-dimensional material layer (transition metal chalcogenide layer) in which a portion of the underlayer is exposed.

The film-forming method for the two-dimensional material layer according to the present embodiment may be performed in any manner rather than being performed by the film-forming apparatus 5 illustrated in FIG. 5. The film-forming method for the two-dimensional material layer according to the present embodiment may be performed in a substrate system in which a plurality of processing apparatuses are connected to a transfer chamber (none of which is shown), and the substrate W can be transferred between the transfer chamber and the plurality of processing apparatuses.

Any of the plurality of processing apparatuses may be a hydrophilizing processing apparatus 6 illustrated in FIG. 6. For example, the hydrophilizing processing apparatus 6 may be a coater configured to apply the hydrophilizing processing liquid, or may be a UV ozone apparatus. The substrate W is transferred to the hydrophilizing processing apparatus 6 by the substrate transfer apparatus provided in the transfer chamber. The hydrophilizing processing liquid is applied to the substrate by the coater configured to apply the hydrophilizing processing liquid. The hydrophilizing processing liquid including ozone water, and irradiation with UV light are performed in the UV ozone apparatus.

Subsequently, the substrate W is transferred from the hydrophilizing processing apparatus 6 to a liquid precursor coater 7 through the transfer chamber by the substrate transfer apparatus provided in the transfer chamber. Any of the plurality of processing apparatuses may be the liquid precursor coater 7 illustrated in FIG. 6. The liquid precursor raw material is applied to the substrate by the liquid precursor coater 7. The liquid precursor raw material over the substrate is heated, and the solvent volatilizes and Mo remains, thereby forming an Mo layer over the underlayer.

Subsequently, the substrate W is transferred from the liquid precursor coater 7 to a heating furnace or a CVD apparatus 8 through the transfer chamber by the substrate transfer apparatus provided in the transfer chamber. Any of the plurality of processing apparatuses may be the heating furnace or CVD apparatus 8 illustrated in FIG. 6. The chalcogen element-including gas is supplied to the heating furnace or CVD apparatus 8. Also, the heating furnace or CVD apparatus 8 forms the two-dimensional material layer by chalcogenizing the Mo layer in a state in which the substrate W is heated.

The transfer chamber and the plurality of processing apparatuses may be in a predetermined pressure-reduced atmosphere, or may be in an open-air atmosphere. The hydrophilizing processing apparatus 6 may be a batch type apparatus configured to process a plurality of substrates W at one time in an open-air atmosphere, or may be a single-wafer type apparatus configured to process the substrates W one by one.

The liquid precursor coater 7 is an apparatus configured to perform wet processing of applying the liquid precursor raw material in an open-air atmosphere. The liquid precursor coater 7 may be a batch type apparatus, or may be a single-wafer type apparatus.

The heating furnace or CVD apparatus 8 is an apparatus configured to form the two-dimensional material layer by heating the substrate W and chalcogenizing the Mo layer over the underlayer in an open-air atmosphere or predetermined pressure-reduced atmosphere and in a gas atmosphere including a chalcogen element. The heating furnace or CVD apparatus 8 may be a batch type apparatus, or may be a single-wafer type apparatus. Although the liquid precursor coater 7 and the heating furnace or CVD apparatus 8 have been described as separate apparatuses, these may be a single apparatus.

As described above, according to the film-forming method and apparatus for the two-dimensional material layer according to the present embodiment, the precursor raw material is selectively supplied to the surface of the underlayer exposed due to the discontinuous growth of the two-dimensional material layer. The two-dimensional material layer is selectively formed in the exposed portions of the underlayer over the substrate surface, thereby forming the discontinuous film into a continuous two-dimensional material layer.

According to one aspect of the present disclosure, it is possible to selectively supply the precursor raw material to the surface of the underlayer not covered by the two-dimensional material layer, thereby forming the continuous two-dimensional material layer.

The film-forming method and apparatus for the two-dimensional material layer according to the present embodiment should be considered to be exemplary and not restrictive in all respects. The embodiments can be modified and improved in various forms without departing from the scope and intent of claims recited. The matters described in the above embodiments can be employed in other configurations if there is no contradiction, and can be combined if there is no contradiction.

What is claimed is:

1. A film-forming method for a two-dimensional material layer, the film-forming method comprising:
(A) providing a substrate in which a portion of an underlayer is exposed from a two-dimensional material layer formed over the underlayer;
(B) supplying a liquid precursor raw material including a transition metal onto the substrate; and
(C) supplying a gas including a chalcogen element, thereby forming the two-dimensional material layer over the exposed underlayer.

2. The film-forming method for the two-dimensional material layer according to claim 1, wherein
a transition metal-including layer is formed over the exposed underlayer by volatilizing the liquid precursor raw material over the substrate.

3. The film-forming method for the two-dimensional material layer according to claim 1, wherein
the two-dimensional material layer is hydrophobic with respect to the liquid precursor raw material.

4. The film-forming method for the two-dimensional material layer according to claim 1, wherein
(B) and (C) are repeatedly performed in order a set number of times.

5. The film-forming method for the two-dimensional material layer according to claim 1, further comprising:
(D) hydrophilizing the substrate before the supply of the liquid precursor raw material.

6. The film-forming method for the two-dimensional material layer according to claim 5, wherein
(B), (C), and (D) are repeatedly performed in order a set number of times.

7. The film-forming method for the two-dimensional material layer according to claim 1, wherein
in (C), the two-dimensional material layer is formed in a horizontal direction of the substrate.

8. The film-forming method for the two-dimensional material layer according to claim 1, wherein
the liquid precursor raw material is a liquid raw material in which a raw material of Mo or W is dissolved in a solvent.

9. The film-forming method for the two-dimensional material layer according to claim 1, wherein
the gas including the chalcogen element is a gas including S, Se, or Te.

10. The film-forming method for the two-dimensional material layer according to claim 1, wherein
in (B), an additive is added to the liquid precursor raw material, and is supplied.

11. The film-forming method for the two-dimensional material layer according to claim 10, wherein
the additive includes K, Na, F, Cl, Br, or I.

12. The film-forming method for the two-dimensional material layer according to claim 1, wherein
the two-dimensional material layer is a transition metal chalcogenide layer.

13. The film-forming method for the two-dimensional material layer according to claim 12, wherein
the transition metal chalcogenide layer is MoS₂ MoSe₂ MoTe₂ WS₂ WSe₂ or WTe₂.

14. The film-forming method for the two-dimensional material layer according to claim 2, wherein
the supply of the liquid precursor raw material onto the substrate, and the volatilization of the liquid precursor raw material over the substrate by heating are repeatedly performed until the transition metal-including layer is formed over the exposed underlayer.

15. A film-forming apparatus, comprising:
a chamber defining a processing chamber configured to be reduced in pressure;
a substrate holder provided in the chamber and configured to hold a substrate;
a first nozzle configured to supply, to a surface of the substrate, a liquid precursor raw material including a transition metal;
a gas supply configured to supply a gas including a chalcogen element into the chamber; and
a heater configured to heat the substrate.

16. The film-forming apparatus according to claim 15, wherein
the substrate holder includes a rotation holder configured to rotatably hold the substrate.

17. The film-forming apparatus according to claim 15, further comprising:
a second nozzle configured to supply a hydrophilizing processing liquid used for performing hydrophilizing processing on the surface of the substrate.

18. The film-forming apparatus according to claim 15, further comprising:
a controller including a memory and a processor coupled to the memory, the controller being configured to control the heater to heat the substrate to volatilize a solvent in the liquid precursor raw material.

19. The film-forming apparatus according to claim 18, wherein
the controller is configured to supply the gas including the chalcogen element into the chamber in a state in which the substrate is heated after the volatilization of the solvent, thereby forming a transition metal chalcogenide layer.

20. The film-forming apparatus according to claim 15, wherein
the substrate transferred into the film-forming apparatus includes a transition metal chalcogenide layer in which a portion of an underlayer is exposed.
